(19) United States
(12) Patent Application Publication
(10) Pub. No.: US 2026/0013154 A1
(43) Pub. Date: Jan. 8, 2026

(54) SEMICONDUCTOR DEVICE AND MANUFACTURING METHOD OF SEMICONDUCTOR DEVICE

(71) Applicant: ROHM CO., LTD., Kyoto (JP)

(72) Inventor: Masahiko TSUTSUI, Kyoto (JP)

(73) Assignee: ROHM CO., LTD., Kyoto (JP)

(21) Appl. No.: 19/247,824

(22) Filed: Jun. 24, 2025

(30) Foreign Application Priority Data
Jul. 3, 2024 (JP) 2024-107501

(51) Int. Cl. H10D 8/25; H10D 8/01; H10D 62/10; H10D 62/60; H10D 64/66

(52) U.S. Cl. CPC H10D 8/25; H10D 8/022; H10D 62/107; H10D 62/124; H10D 62/60; H10D 64/661

(57) ABSTRACT

A semiconductor device includes a semiconductor layer, a trench with the semiconductor layer being a bottom surface thereof, and an insulating layer covering a surface of the trench. The semiconductor layer includes a first contact region, a second contact region located on a first impurity region in a surface portion of the semiconductor layer and separated from the first contact region, and a second impurity region located on the first impurity region below the second contact region and in contact with both the first impurity region and the second contact region. The first impurity region and the first contact region are separated from each other.

### CROSS REFERENCE TO RELATED APPLICATION

This application is based upon and claims the benefit of priority of the prior Japanese Patent Application No. 2024-107501, filed on Jul. 3, 2024, the entire contents of which are incorporated herein by reference.

### TECHNICAL FIELD

The present disclosure relates to a semiconductor device and a manufacturing method of a semiconductor device.

### BACKGROUND ART

Japanese Patent Application Laid-open Publication No. H7-312428 discloses a Zener diode formed on a semiconductor substrate.

### BRIEF DESCRIPTION OF THE DRAWINGS

FIG. 1 is a schematic plan view of a semiconductor device of an embodiment.

FIG. 2 is a schematic cross-sectional view along the line II-II of FIG. 1.

FIG. 3 is a schematic cross-sectional view for explaining one example of a manufacturing method of a semiconductor device of an embodiment.

FIG. 4 is a schematic cross-sectional view for explaining one example of a manufacturing method of a semiconductor device of an embodiment.

FIG. 5 is a schematic cross-sectional view for explaining one example of a manufacturing method of a semiconductor device of an embodiment.

FIG. 6 is a schematic cross-sectional view for explaining one example of a manufacturing method of a semiconductor device of an embodiment.

FIG. 7 is a schematic cross-sectional view for explaining one example of a manufacturing method of a semiconductor device of an embodiment.

FIG. 8 is a schematic cross-sectional view for explaining one example of a manufacturing method of a semiconductor device of an embodiment.

FIG. 9A is a schematic cross-sectional view for explaining one example of a manufacturing method of each trench structure.

FIG. 9B is a schematic cross-sectional view for explaining one example of a manufacturing method of each trench structure.

FIG. 9C is a schematic cross-sectional view for explaining one example of a manufacturing method of each trench structure.

FIG. 9D is a schematic cross-sectional view for explaining one example of a manufacturing method of each trench structure.

FIG. 9E is a schematic cross-sectional view for explaining one example of a manufacturing method of each trench structure.

FIG. 10 is a schematic cross-sectional view showing a semiconductor device according to a reference example.

### DETAILED DESCRIPTION OF EMBODIMENTS

Below, an embodiment of the present disclosure will be explained in detail with reference to the appended drawings. In the description below, the same components or components having the same function are given the same reference character and the descriptions thereof will not be repeated. The term “same” or any other terms similar to that in this specification are not limited to “exactly the same”. The figures are for explaining the embodiment conceptually, and therefore, the dimensions and ratios of the respective components may differ from the actual dimensions and ratios.

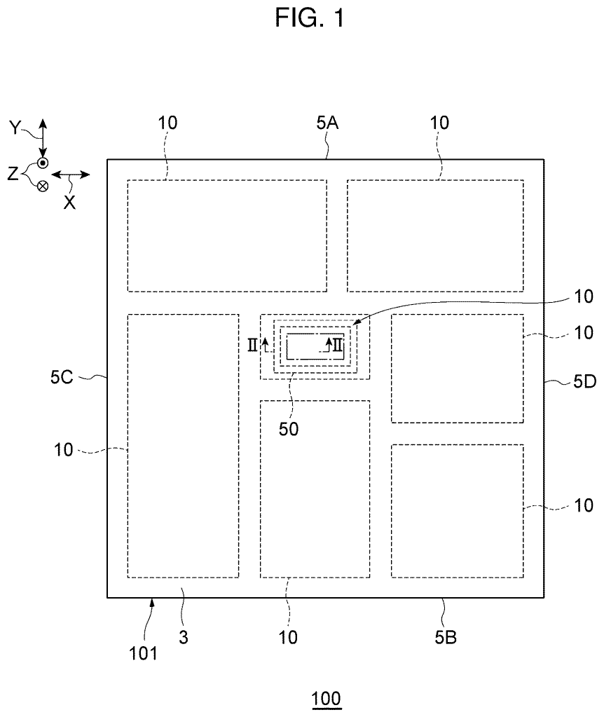

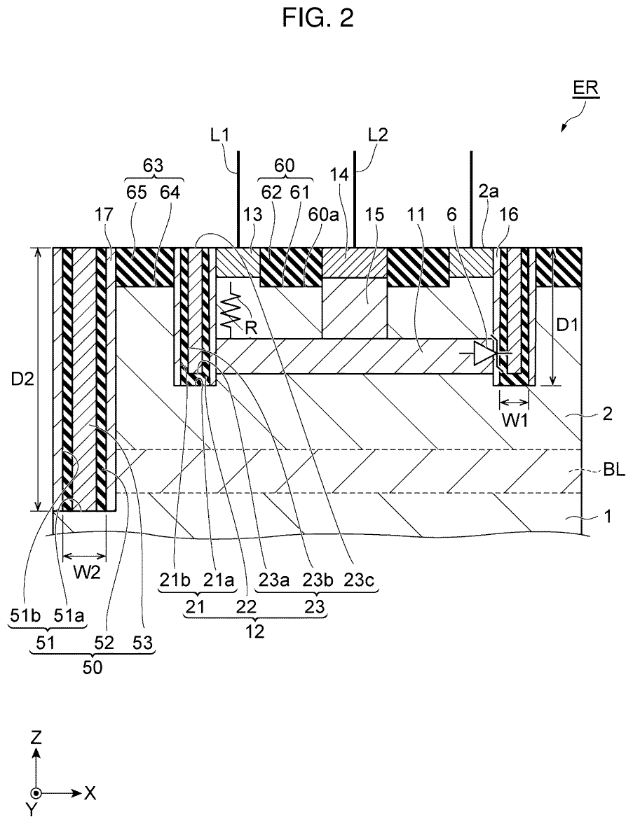

FIG. 1 is a schematic plan view of a semiconductor device of an embodiment of the present disclosure. FIG. 2 is a schematic cross-sectional view along the line II-II of FIG. 1. Wiring lines are omitted from FIGS. 1 and 2. As shown in FIG. 1, a semiconductor device 100 includes a silicon chip 101 (semiconductor chip) having a cuboid shape. The chip 101 is one of a plurality of devices formed on a silicon wafer with a diameter of 300 mm (approximately 12 inch), for example. The semiconductor device 100 includes a chip-shaped integrated circuit (IC) device, for example. The semiconductor device 100 may be referred to as an SSI (Small Scale IC), MSI (Medium Scale IC), LSI (Large Scale IC), VLSI (Very Large Scale IC), ULSI (Ultra Large Scale IC) and the like, based on the number of circuit elements integrated therein. The semiconductor device 100 is used for LSI equipped with a gate clamper, for example.

The semiconductor chip 101 has a pair of main surfaces, a first main surface 3 and a second main surface 4, and a first side surface 5A, a second side surface 5B, a third side surface 5C, and a fourth side surface 5D that connect the first main surface 3 and the second main surface 4. Below, the direction in which the first side surface 5A and the second side surface 5B extend in a plan view is referred to as the first direction X, the direction in which the third side surface 5C and the fourth side surface 5D extend in a plan view is referred to as the second direction Y, and the normal direction of the first main surface 3 and the second main surface 4 is referred to as the third direction Z. The second direction Y is a direction intersecting with the first direction X in a plan view, and the third direction Z corresponds to the thickness direction of the chip 101. In this specification, “a plan view” corresponds to a view from the third direction Z.

The first main surface 3 and the second main surface 4 are formed in a quadrangular shape when viewed from the third direction Z, but are not limited to this. In this embodiment, the first main surface 3 is the top surface, and the second main surface 4 is the bottom surface. Therefore, configurations located near the first main surface 3 in the third direction Z correspond to configurations located on the top side (upper side) of the semiconductor device 100, and configurations located near the second main surface 4 in the third direction Z correspond to configurations located on the bottom side (lower side) of the semiconductor device 100.

In the semiconductor device 100, a plurality of device regions 10 are defined on the first main surface 3, separated from one another. In the semiconductor device 100, the number and arrangement of the plurality of device regions 10 may be set as appropriate. Each of the plurality of device regions 10 includes function devices formed using areas inside and outside the chip 101. The function devices include at least one of a semiconductor switching device, a semiconductor rectifier device, and a receptor device, for example. The function devices may also include a circuit network that has a combination of at least two of the semiconductor switching device, semiconductor rectifier device and receptor device.

The semiconductor switching device includes at least one of a bipolar transistor, a metal insulator semiconductor field effect transistor (MISFET), a bipolar junction transistor (BJT), an insulated gate bipolar junction transistor (IGBT), and a JFET, for example. The semiconductor rectifier device may include at least one of a pn junction diode, a pin junction diode, a Zener diode, a Schottky barrier diode, and a fast recovery diode. The receptor device may include at least one of a resistance, capacitor, inductor and fuse.

For the MISFET, a MOSFET (metal oxide semiconductor field effect transistor) may be used. The MOSFET may be an enhancement type or a depression type. The MOSFET may have a planar structure, or vertical structure. The element region ER may be a power transistor. The cathode-to-anode voltages of MISFETs include HV (high voltage: between 100V and 1000V, for example), MV (middle voltage: between 30V and 100V, for example) and LV (low voltage: between 1V and 30V, for example). In addition, as the element region ER formed in the device region 10, an optical device such as a light emitting element or a light receiving element can be used.

In this embodiment, the semiconductor material that constitutes the chip 101 is silicon (Si), but is not limited thereto. A compound semiconductor may alternatively be used for the semiconductor material that constitutes the chip 101. The compound semiconductor may be a III-V compound semiconductor, IV-IV compound semiconductor, and an alloy semiconductor using these semiconductors. The III-V compound semiconductor is a Ga semiconductors such as GaAs or GaN, for example. The IV-IV compound semiconductor is an Si semiconductors such as SiC and SiGe, for example.

As illustrated in FIGS. 1 and 2, the device regions 10 constituting the semiconductor device include a semiconductor substrate 1 and a semiconductor layer 2 located on the semiconductor substrate 1. The semiconductor substrate 1 functions as a base substrate in forming the semiconductor layer 2, and may be a single crystal Si substrate, single crystal SiC substrate, or the like, for example. The semiconductor layer 2 is an epitaxial layer formed on the semiconductor substrate 1 as a base. A main surface (front surface) 2a of the semiconductor layer 2 corresponds to the first main surface 3 of the chip 101, but is not limited thereto. In the device region 10, a buried region BL, an element region ER located on the buried region BL, and a trench structure 50 surrounding the element region ER in a plan view are defined. The buried region BL is formed at least in the semiconductor layer 2. In addition to the semiconductor layer 2, the buried region BL may be formed in the semiconductor substrate 1.

For the respective semiconductor regions constituting the semiconductor device, n type is considered the first conductivity type, and p type is considered the second conductivity type that differs from the first conductivity type in this embodiment, but those conductivity types may be switched. That is, the first conductivity type may be p type and the second conductivity type may be n type. Examples of the p type impurity (trivalent atom) includes boron (B). Examples of the n type impurity (pentavalent atom) includes phosphorus (P) and arsenic (As). The semiconductor substrate 1 of this embodiment is made of Si. In this embodiment, the semiconductor substrate 1 is the second conductivity type, the semiconductor layer 2 is the first conductivity type, and the buried region BL is the first conductivity type.

The impurity concentration of the semiconductor substrate 1 may be 1.0×10¹⁵ cm⁻³ or greater and less than or equal to 1.0×10¹⁹ cm⁻³. The thickness of the semiconductor substrate 1 may be 50 μm or greater and less than or equal to 500 μm. The impurity concentration of the buried region BL may be 1.0×10¹⁷ cm⁻³ or greater and less than or equal to 1.0×10²⁰ cm⁻³. The impurity concentration of the semiconductor layer 2 may be 1.0×10¹⁵ cm⁻³ or greater and less than or equal to 1.0×10¹⁹ cm⁻³. The thickness of the semiconductor layer 2 may be 5 μm or greater and less than or equal to 50 μm.

There is no special limitation on the structure of the element region. Below, the structure of the element region ER of this embodiment will be explained. In this embodiment, the element region ER has a first impurity region 11 separated from the semiconductor substrate 1 and located in the semiconductor layer 2, a trench structure 12 formed in the semiconductor layer 2 and adjacent to the first impurity region 11, a first contact region 13 located in the semiconductor layer 2 above the first impurity region 11, a second contact region 14 located in the semiconductor layer 2, and a second impurity region 15 located in the semiconductor layer 2 and in contact with both the first impurity region 11 and the second contact region 14. In addition, the element region ER may include wiring L1 connected to the first contact region 13 and wiring L2 connected to the second contact region 14. In the element region ER, a Zener diode 6 is formed by a part of the semiconductor layer 2, the first impurity region 11, and the trench structure 12. Also, the first contact region 13, the second contact region 14, and the second impurity region 15 form the current path for the Zener diode 6 in the element region ER.

The first impurity region 11 is a well region of the second conductivity type, disposed in the center of the element region ER. The first impurity region 11 is separated from the main surface 2a of the semiconductor layer 2. In other words, the first impurity region 11 is located below the main surface 2a of the semiconductor layer 2 in the third direction Z. In addition, the first impurity region 11 is separated from the buried region BL. In other words, the first impurity region 11 is located above the buried region BL in the third direction Z. The first impurity region 11 is in contact with the trench structure 12 and has the trench structure 12 at both ends in the first direction X and the second direction Y. The first impurity region 11 is located above the bottom of the trench structure 12 in the third direction Z, but is not limited thereto. The first impurity region 11 is formed by introducing (adding, doping) a second conductivity type impurity to a part of the semiconductor layer 2, for example. The impurity concentration of the first impurity region 11 is 1.0×10¹⁵ cm⁻³ or greater and less than or equal to 1.0×10¹⁹ cm⁻³, for example. The dimension of the first impurity region 11 along the third direction Z is 2 μm or greater and less than or equal to 4 μm, for example.

The trench structure 12 is a part (shallow trench) adjacent to the first impurity region 11 in a plan view, and is separated from the buried region BL. In other words, the trench structure 12 is located above the buried region BL in the third direction Z. The trench structure 12 has a trench 21 with the semiconductor layer 2 being the bottom surface thereof, an insulator 22 that covers the surface of the trench 21, and a conductor 23 located inside the trench 21 and separated from the semiconductor layer 2.

The trench 21 is a recess (trench) formed in the semiconductor layer 2, extending from the first main surface 3 toward the second main surface 4 in the third direction Z. The semiconductor layer 2 serves as the bottom surface of the trench 21. The trench 21 has a ring shape that surrounds the first impurity region 11, the first contact region 13, and the second contact region 14 in a plan view, for example, but is not limited thereto. The trench 21 may have a shape that partially surrounds the first impurity region 11 in a plan view, for example. The bottom surface 21a of the trench 21 (a part of the surface of the trench 21) is located closer to the semiconductor substrate 1 than the first impurity region 11 in the third direction Z, but is separated from the buried region BL. In other words, the bottom surface 21a is located below the first impurity region 11. From the perspective of reducing the size of the Zener diode 6 and the like, the shorter side of the trench 21 in a plan view (width W1) is set to 0.5 μm or greater and less than or equal to 2.4 μm, for example. The dimension of the trench 21 along the third direction Z (depth D1) is 4 μm or greater and less than or equal to 8 μm, for example. Thus, the ratio of the width W1 of the trench 21 to the depth D1 of the trench 21 is 0.062 or greater and less than or equal to 0.6, for example. The width W1 stays unchanged, but is not limited thereto. For example, the width W1 may become smaller as it goes down in the third direction Z. Therefore, in this embodiment, the width W1 corresponds to the maximum value of the shorter side of the trench 21 in a plan view.

The side surface 21b of the trench 21 (another part of the surface of the trench 21) is located inside the semiconductor layer 2, and is defined by a third impurity region 16 of the first conductivity type. The third impurity region 16 is a region formed by the side surface 21b in the semiconductor layer 2, and is adjacent to the first impurity region 11. In this embodiment, the third impurity region 16 is a region formed during the forming process of the trench structure 12 as described below, and thus, is considered a part of the trench structure 12 and the side surface 21b of the trench 21. Therefore, the side surface 21b of the trench 21 in the trench structure 12 (which actually is the third impurity region 16) is adjacent to the first impurity region 11. As a result, a pn junction is formed between the first impurity region 11 and the third impurity region 16. Thus, the third impurity region 16 can serve as a region that functions as one of the anode and the cathode of the Zener diode 6. Similarly, the third impurity region 16 can serve as a region that functions as the other of the anode and the cathode of the Zener diode 6. From the perspective of the performance and the like of the Zener diode 6, the impurity concentration of the third impurity region 16 is 1.0×10¹⁷ cm⁻³ or greater and less than or equal to 1.0×10²⁰ cm⁻³, for example, and the thickness of the third impurity region 16 along the direction orthogonal to the third direction Z is 30 nm or greater and less than or equal to 300 nm, for example. The impurity concentration of the third impurity region 16 is significantly higher than the impurity concentration of the semiconductor layer 2. Therefore, the third impurity region 16 functions as the primary part of the conductive channel between the first impurity region 11 and the first contact region 13, which is a part of the conductive channel in the Zener diode 6.

The insulator 22 is an insulating component that prevents the semiconductor layer 2 and the conductor 23 from making contact with each other, and covers the bottom surface 21a and side surface 21b of the trench 21. The insulator 22 is formed of an oxide insulating film such as a silicon oxide film or an aluminum oxide film, a nitride insulating film such as a silicon nitride film, or an oxynitride insulating film such as a silicon oxynitride film, for example. From the perspective of preventing a short circuit between the semiconductor layer 2 and the conductor 23 and the like, the thickness of the insulator 22 is 3 nm or greater and less than or equal to 200 nm, for example. In the insulator 22, the thickness of the part that is in contact with the bottom surface 21a only, and the thickness of the part that is in contact with the side surface 21b only may differ from each other, or may be the same as each other.

The conductor 23 is a conductive component located inside the insulator 22 in the trench 21. By applying a voltage to the conductor 23, parasitic resistance R between the third impurity region 16 and the semiconductor layer 2 can be reduced. In this case, the conductor 23 can have the function of reducing the resistance in the conductive channel that runs through the Zener diode 6. However, the conductor 23 may also be a floating state. The bottom surface 23a and side surface 23b are covered by the insulator 22. The top surface 23c of the conductor 23 is exposed from the insulator 22. When a prescribed voltage is applied to the conductor 23, the top surface 23c may be connected to wiring that is not shown in the figure. The bottom surface 23a of the conductor 23 is located closer to the semiconductor substrate 1 than the first impurity region 11 in the third direction Z. In other words, the bottom surface 23a of the conductor 23 is located below the first impurity region 11. The conductor 23 is a metal such as aluminum (Al), copper (Cu), molybdenum (Mo), or tungsten (W), or polysilicon of the first or second conductivity type, for example.

The first contact region 13 is a region that functions as one of the anode and cathode of the Zener diode 6, and is located above the first impurity region 11 and on the main surface 2a of the semiconductor layer 2. In addition, the first contact region 13 is the first conductivity type and in contact with the side surface 21b of the trench 21 (that is, the third impurity region 16). In a plan view, the first contact region 13 is located between the trench 21 and the second contact region 14. The first contact region 13 is separated from the first impurity region 11. The first contact region 13 is located inside the trench structure 12 in a plan view, and surrounds at least a part of the second contact region 14. In this embodiment, the first contact region 13 and a part of the third impurity region 16 located above the first impurity region 11 in the third direction Z are different components, but the present disclosure is not limited thereto. A part of the side surface 21b may be constituted of the first contact region 13. The impurity concentration of the first contact region 13 is greater than the impurity concentration of the first impurity region 11 and the impurity concentration of the second impurity region 15, and is 1.0×10¹⁸ cm⁻³ or greater and less than or equal to 1.0×10²¹ cm⁻³, for example.

The second contact region 14 is a region that functions as the other of the anode and cathode of the Zener diode 6, and is located above the first impurity region 11 on the main surface 2a of the semiconductor layer 2. The second contact region 14 is the second conductivity type and separated from the first contact region 13. In addition, the second contact region 14 is separated from the trench structure 12. The impurity concentration of the second contact region 14 is greater than the impurity concentration of the first impurity region 11 and the impurity concentration of the second impurity region 15, and is 1.0×10¹⁸ cm⁻³ or greater and less than or equal to 1.0×10²¹ cm⁻³, for example.

The second impurity region 15 is a region that connects the first impurity region 11 and the second contact region 14, located above the first impurity region 11 and below the second contact region 14. The second impurity region 15 is the second conductivity type and in contact with both the first impurity region 11 and the second contact region 14. That is, the second contact region 14, the second impurity region 15, and the first impurity region 11 are the second conductivity type, respectively. The second impurity region 15 is separated from the first contact region 13 or the trench structure 12. The impurity concentration of the first impurity region 15 is 1.0×10¹⁷ cm⁻³ or greater and less than or equal to 1.0×10²⁰ cm⁻³, for example.

The first contact region 13 is applied with one of the anode voltage and cathode voltage via the wiring L1. The second contact region 14 is applied with the other of the anode voltage and cathode voltage via the wiring L2. In this case, electric current flows from the second contact region 14 to the first contact region 13 via the first impurity region 11, the second impurity region 15, the semiconductor layer 2, the third impurity region 16, and the like, for example.

Next, the trench structure 50 will be explained in detail. The trench structure 50 is an element separating structure that electrically separates the element region ER from other device regions 10, and is deep trench isolation (DTI) formed in the semiconductor substrate 1. The trench structure 50 has a ring shape surrounding the element region ER in a plan view. Thus, the element region ER is surrounded by the trench structure 50 and the buried region BL. The trench structure 50 is separated from the element region ER, but in contact with the buried region BL. The trench structure 50 has a trench 51 (second trench), an insulating layer 52 that partially covers the surface of the trench 51, and a conductor (second conductor) 53 located inside the trench 51 and separated from the semiconductor layer 2.

The trench 51 is a recess (trench) that runs through the semiconductor layer 2, extending from the first main surface 3 toward the second main surface 4 in the third direction Z. The semiconductor substrate 1 serves as the bottom surface of the trench 51. The trench 51 has a ring shape surrounding the respective components of the Zener diode 6 (the first impurity region 11, the trench structure 12, the first contact region 13, the second contact region 14, the second impurity region 15 and the like) in a plan view, for example. The bottom surface 51a of the trench 51 (a part of the surface of the trench 51) is located below the buried region BL in the third direction Z and separated from the buried region BL. The shorter side of the trench 51 in a plan view (width W2) is greater than the width W1 of the trench 21, and is set to 2.5 μm or greater and less than or equal to 4.5 μm, for example. Thus, the width W2 of the trench 51 is 104% or greater and less than or equal to 900% of the width W1 of the trench 21, for example. The dimension of the trench 51 along the third direction (depth D2) is greater than the dimension of the trench 21 (depth D1), and is set to 20 μm or greater and less than or equal to 40 μm, for example. The width W2 remains unchanged, but is not limited thereto. For example, the width W2 may become smaller as it goes down in the third direction Z. Therefore, in this embodiment, the width W2 corresponds to the maximum value of the shorter side of the trench 51 in a plan view. The ratio of the width W2 of the trench 51 to the depth D2 of the trench 51 is 0.062 or greater and less than or equal to 0.23, for example. In addition, the ratio of the width W1 of the trench 21 to the depth D1 of the trench 21 is 27% or greater and less than or equal to 960% of the ratio of the width W2 of the trench 51 to the depth D2 of the trench 51, for example. As described below, the trench 51 is formed at the same time as the trench 21.

The side surface 51b of the trench 51 (another part of the surface of the trench 51) is located in the semiconductor substrate 1 and semiconductor layer 2, and is defined by a fourth impurity region 17 of the first conductivity type. The fourth impurity region 17 is a region formed by the side surface 51b in the semiconductor substrate 1 and semiconductor layer 2. In this embodiment, the fourth impurity region 17 is a region formed during the forming process of the trench structure 50 as described below, and thus, is considered a part of the trench structure 50 and the side surface 51b of the trench 51. As described below, the fourth impurity region 17 is formed as the same time as the third impurity region 16. Thus, the impurity concentration and thickness of the fourth impurity region 17 is approximately the same as the impurity concentration and thickness of the third impurity region 16.

The insulating layer 52 is a component that prevents the semiconductor layer 2 and the conductor 53 from making contact with each other, and at least covers the side surface 51b of the trench 51. In this embodiment, the insulating layer 52 covers a part of the bottom surface 51a of the trench 51 in addition to the side surface 51b of the trench 51. In other words, another part of the bottom surface 51a of the trench 51 is exposed from the insulating layer 52. The insulating layer 52 is formed of an oxide insulating film, nitride insulating film, oxynitride insulating film, or the like as described above, for example. From the perspective of preventing the conductor 53 from making contact with the semiconductor layer 2 and the like, the thickness of the insulating layer 52 is set to 3 nm or greater and less than or equal to 200 nm, for example. As described below, the insulating layer 52 is formed at the same time as the insulator 22.

The conductor 53 is a component located on the insulating layer 52 in the trench 50, and is in contact with the semiconductor substrate 1. The conductor 53 is a frame-shaped conductor that is surrounded by the insulating layer 52 in a plan view, extending from the first main surface 3 toward the second main surface 4 in the third direction Z. The conductor 53 is embedded in trench 51, and in contact with a part of the semiconductor substrate 1 below the buried region BL. This makes the potential of the conductor 53 aligned with the potential of the semiconductor substrate 1. The conductor 53 is a metal such as aluminum (Al), copper (Cu), molybdenum (Mo), or tungsten (W), or polysilicon having the first or second conductivity type, for example. As described below, the conductor 53 is formed at the same time as the conductor 23.

From the perspective of reducing a leak current and the like, STI (shallow trench isolation) 60 is formed between the first contact region 13 and the second contact region 14. The STI 60 is a part where an insulator 62 is embedded in a recess 61 formed in a part of the semiconductor layer 2 between the first contact region 13 and the second contact region 14. The STI 60 has a ring shape that surrounds the second contact region 14 in a plan view, for example, but is not limited thereto. From the perspective of reducing a leak current between the first contact region 13 and the second contact region 14, a bottom surface 60a of the STI 60 is located below the bottom surface of the first contact region 13 and the bottom surface of the second contact region 14.

Also, from the perspective of reducing a leak current, STI (shallow trench isolation) 63 is formed between the first contact region 13 and the trench structure 50. The STI 63 is a part where an insulator 65 is embedded in a recess 64 formed in a part of the semiconductor layer 2 between the first contact region 13 and the trench structure 50. The STI 63 has a ring shape that surrounds the first contact region 13 in a plan view, for example, but is not limited thereto. The STI 63 is located outside the trench structure 12 in a plan view.

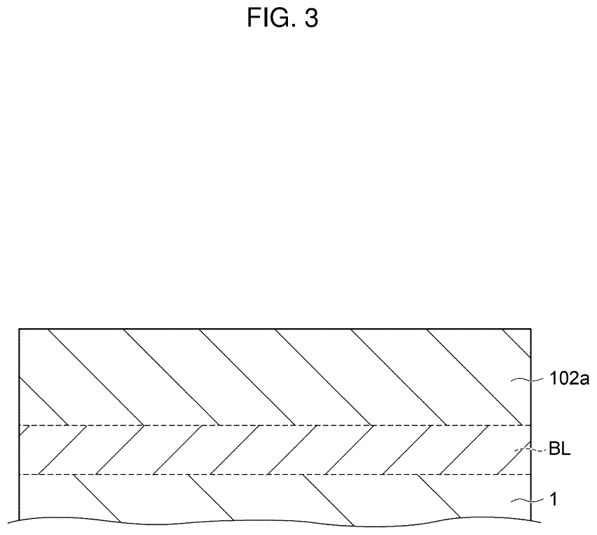

Next, with reference to FIGS. 3 to 8, an example of the manufacturing method of the semiconductor device 100 according to this embodiment will be explained. FIGS. 3 to 8 are each a schematic cross-sectional view for explaining one example of the manufacturing method of the semiconductor device 100 according to this embodiment.

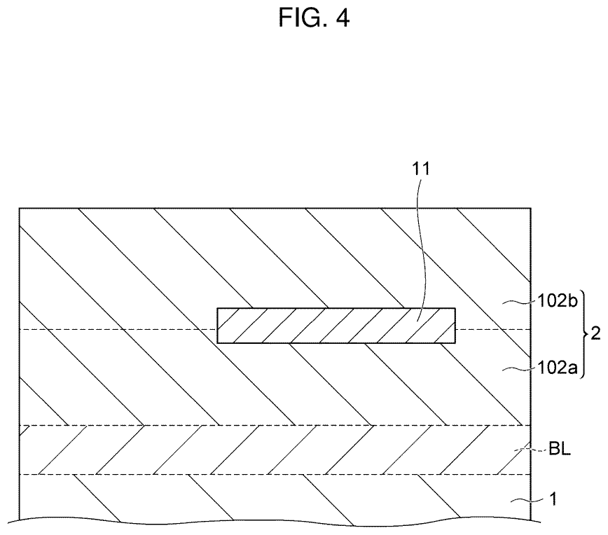

First, as illustrated in FIGS. 3 and 4, the semiconductor layer 2 of the first conductivity type is formed on the semiconductor substrate 1 (Step 1). In Step 1, a first epitaxial layer 102a is formed by growing a semiconductor on the semiconductor substrate 1 by epitaxy as illustrated in FIG. 3. While the first epitaxial layer 102a is being formed, the buried region BL is formed by adjusting the amount of added impurity, for example. The impurity injection to the semiconductor substrate 1 and/or the first epitaxial layer 102a is performed by a known method such as ion implantation, for example. Next, after injecting a second conductivity type impurity into the first epitaxial layer 102a, a semiconductor layer is formed on the first epitaxial layer 102a by epitaxy. As a result, the semiconductor layer 2 having the first epitaxial layer 102a and the second epitaxial layer 102b as well as the first impurity region 11 is formed as illustrated in FIG. 4.

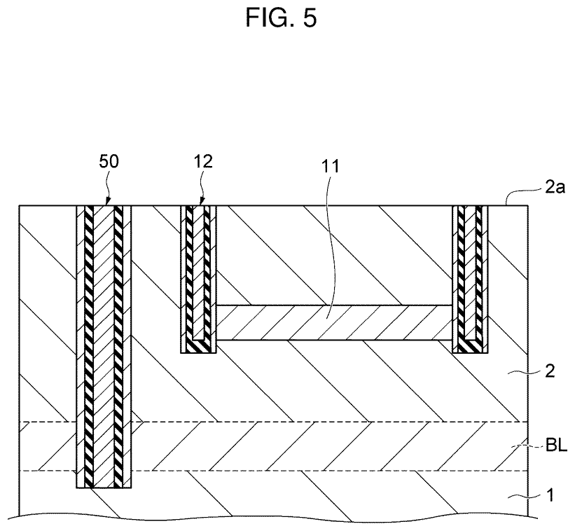

Next, as illustrated in FIG. 5, the trench structure 12 in the semiconductor layer 2 and the trench structure 50 running through the semiconductor layer 2 are formed at the same time (Step 2). A part of the first impurity region 11 may be removed when the trench structure 12 is formed. The first impurity region 11 does not have to be removed during the formation of the trench structure 12. The trench structure 50 is formed in a position separated from the first impurity region 11.

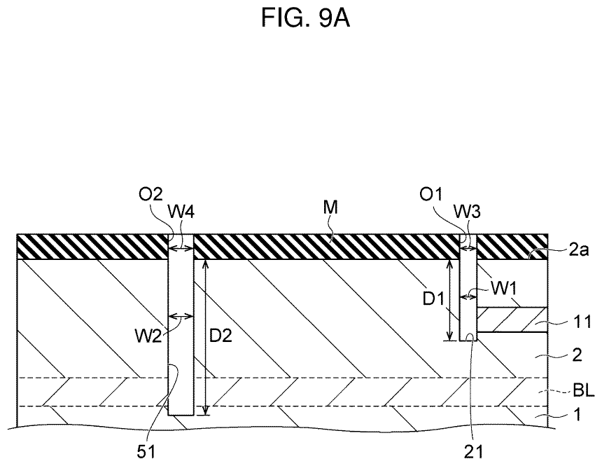

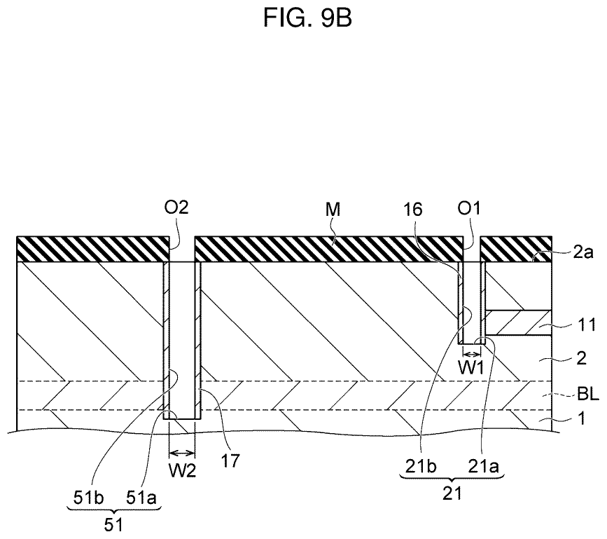

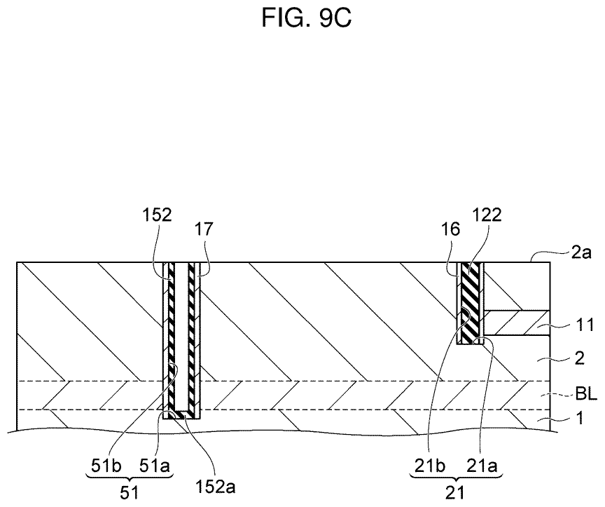

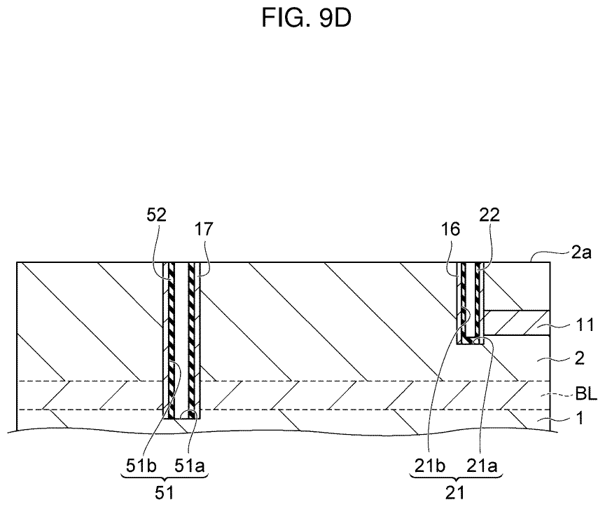

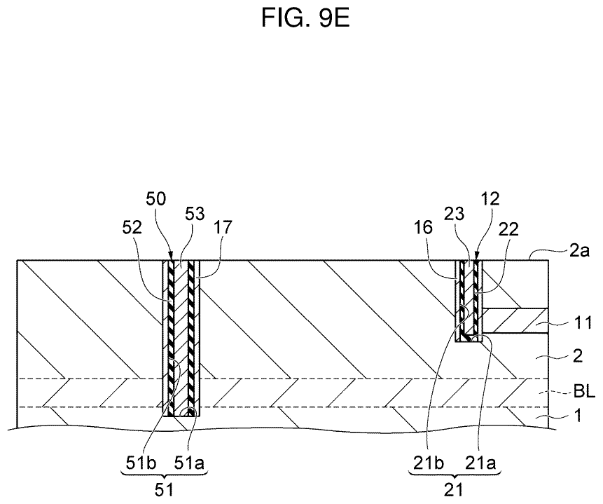

Below, Step 2 will be explained in detail with reference to FIGS. 9A to 9E. FIGS. 9A to 9E are each a schematic cross-sectional view for explaining one example of the manufacturing method of each trench structure.

First, as illustrated in FIG. 9A, the trench 21 having the semiconductor layer 2 as the bottom surface thereof and adjacent to the first impurity region 11 is formed at the same time as the trench 51 that runs through the semiconductor layer 2 (Step 2A). In Step 2A, first, a hard mask M having openings O1, O2 is formed on the main surface 2a of the semiconductor layer 2. Next, in the semiconductor layer 2, etching is performed on the part exposed through the opening O1 and the part exposed through the opening O2 to form the trenches 21 and 51. The hard mask M is a component formed of a material having a low etching rate relative to the etchant for the semiconductor layer 2 such as a silicon oxide film. The opening width W3 of the opening O1 is equal to the maximum value of the width W1 of the trench 21, and the opening width W4 of the opening O2 is equal to the maximum value of the width W2 of the trench 51. The hard mask M has a different shape from the mask used in Step 2.

In Step 2A, the trenches 21 and 51 are formed by anisotropic etching, such as the Bosch process using F radicals, for example. As a result, the width W1 of the trench 21 can be controlled to be equal to or smaller than the opening width W3, and the width W2 of the trench 51 can be controlled to be equal to or smaller than the opening width W4. The etching rate of the part of the semiconductor layer 2 exposed from the opening O1 is made different from the etching rate of the part of the semiconductor layer 2 exposed from the opening O2 mainly based on the difference between the opening widths W3 and W4. Specifically, by making the opening widths W3 and W4 differ from each other, the etching rate of the part of the semiconductor layer 2 exposed from the opening O1 is made higher than the etching rate of the part exposed from the opening O2. This makes it possible to make the depth D1 of the trench 21 smaller than the depth D2 of the trench 51 despite that the trenches 21 and 51 are formed at the same time. This way, in Step 2A, the trench 21 having the semiconductor layer 2 as the bottom surface thereof and the trench 51 having the semiconductor substrate 1 as the bottom surface thereof can be formed.

Next, as shown in FIG. 9B, an impurity of the first conductivity type is introduced into the side surface 21b of the trench 21 and the side surface 51b of the trench 51 (Step 2B). As a result, the third impurity region 16 is formed along the side surface 21b, and the fourth impurity region 17 is formed along the side surface 51b. In Step 2B, the impurity is simultaneously introduced into the side surfaces 21b and 51b by oblique ion implantation using the hard mask M, for example. In Step 2B, an impurity is not introduced to the bottom surface 21a of the trench 21 and the bottom surface 51a of the trench 51, but the present disclosure is not limited thereto.

Next, as shown in FIG. 9C, an insulator 122 filling the trench 21 and an insulating layer 152 covering the trench 51 are simultaneously formed (Step 2C). In Step 2C, the insulator 122 and the insulating layer 152 are simultaneously formed by a known method such as chemical vapor deposition (CVD), for example. In this embodiment, due to differences in width, depth and the like between the trenches 21 and 51, the trench 21 is completely filled with the insulator 122, whereas the trench 51 is not completely filled with the insulating layer 152. Therefore, a portion 152a of the insulating layer 152 located on the bottom surface 51a of the trench 51 becomes thinner than the other portion. Specifically, the thickness of the portion 152a is smaller than the depth of the insulator 122 (that is, the depth D1 of the trench 21). In Step 2C, the trench 21 does not have to be completely filled with the insulator 122. Although not shown in the figure, in Step 2C, the hard mask M can be used, but does not have to be used. If not used, the hard mask Mis removed before Step 2C, for example. Removal of the hard mask M is performed by chemical-mechanical polishing (CMP), for example. The insulator can also be deposited on the main surface 2a of the semiconductor layer 2.

Next, as illustrated in FIG. 9D, a portion of the insulator 122 is removed such that the bottom surface 21a of the trench 21 is not exposed, and a portion 152a of the insulating layer 152 is removed such that the semiconductor substrate 1 is exposed in the trench 51 (Step 2D). In Step 2D, the insulator 122 and the insulating layer 152 are removed by anisotropic etching, for example. In Step 2D, the insulator 122 and the insulating layer 152 are etched to the extent that the portion 152a of the insulating layer 152 is removed. As described above, the thickness of the portion 152a of the insulating layer 152 is smaller than the depth of the insulator 122. This way, the insulator 22 covering the trench 21 and the insulating layer 52 covering the side surface 51b of the trench 51 are formed. In Step 2D, a part or all of the insulator deposited on the main surface 2a may be removed by etching. In Step 2D, a portion of the insulator remains on the main surface 2a, but the present disclosure is not limited thereto. The semiconductor substrate 1 and the semiconductor layer 2 can each function as the etching stopper in Step 2D.

Next, as illustrated in FIG. 9E, the conductor 23, which is to be separated from the semiconductor layer 2, is embedded in the trench 21, and the conductor 53, which is to be in contact with the semiconductor substrate 1, is embedded in the trench 51 (Step 2E). In Step 2E, first, a conductor (not shown) for filling the trenches 21 and 51 is formed by a known method such as sputtering or CVD. The conductor is formed not only in the trenches 21 and 51 but also on the main surface 2a of the semiconductor layer 2. Next, a portion of the conductor located on the main surface 2a of the semiconductor layer 2 is removed by a known method such as CMP. If an insulator, a hard mask M, or the like remained on the main surface 2a of the semiconductor layer 2, that insulator or the like may be removed at the same time as the portion of the conductor located on the main surface 2a of the semiconductor layer 2. By performing Steps 2A to 2E described above, the trench structures 12 and 50 are simultaneously formed as illustrated in FIG. 9E.

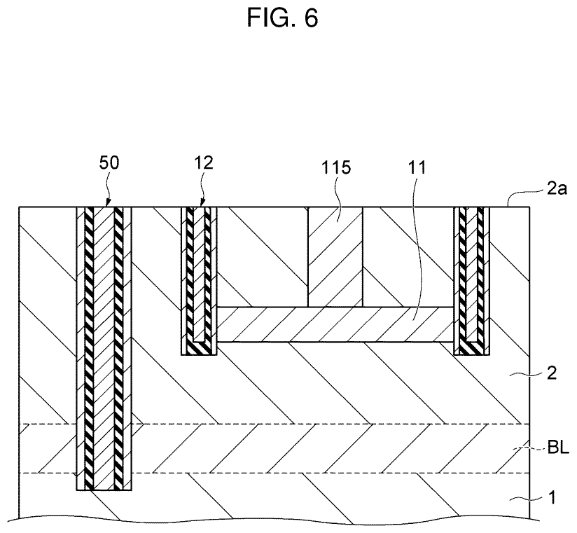

Next, returning to FIG. 6, an impurity region 115 is formed in the semiconductor layer 2. The impurity region 115 is located on the first impurity region 11, making contact with the first impurity region 11 (Step 3). In Step 3, first, a mask (not shown) is formed on the semiconductor layer 2, and thereafter, a second conductivity type impurity is introduced to the portion of the semiconductor layer 2 exposed from the mask. The impurity injection to this portion is performed by a known method such as ion implantation, for example. In addition, the impurity region 115 formed in Step 3 is a region that becomes the second contact region 14 and the second impurity region 15 later.

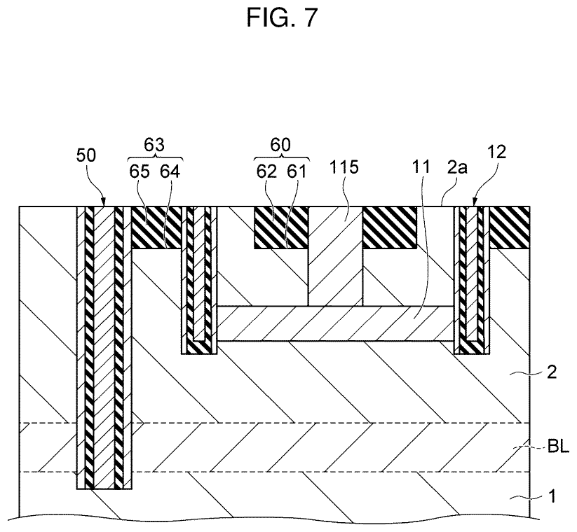

Next, as illustrated in FIG. 7, STIs 60 and 63 are formed (Step 4). In Step 4, first, recesses 61 and 64 are formed in the semiconductor layer 2. The recess 61 is located inside the trench structure 12 and has a ring shape that surrounds the impurity region 115 in a plan view, for example. In one example, the recess 61 is in contact with the impurity region 115 and separated from the trench structure 12. The recess 64 is located outside the trench structure 12 and inside the trench structure 50 in a plan view. In one example, the recess 64 is in contact with the trench structures 12 and 50, but not limited thereto. Next, insulators 62 and 65 that fill the recesses 61 and 64 are formed respectively. In this way, the STI 60 including the recess 61 and the insulator 62, and the STI 63 including the recess 64 and the insulator 65 are formed.

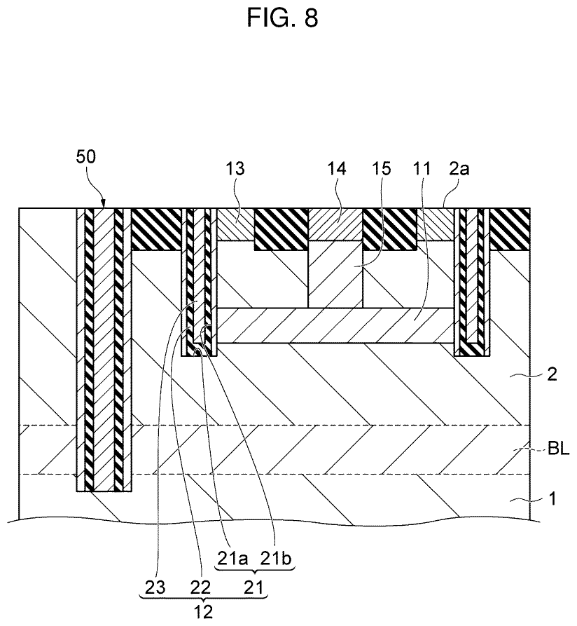

Next, as illustrated in FIG. 8, the first contact region 13 and the second contact region 14 are formed above the main surface 2a of the semiconductor layer 2 in the first impurity region 11 (Step 5). In Step 5, first, one of the first contact region 13 and the second contact region 14 is formed. For example, using a mask (not shown), an impurity of one of the first conductivity type and the second conductivity type is introduced to the portion of the semiconductor layer 2 exposed from the mask. Next, the other of the first contact region 13 and the second contact region 14 is formed. For example, using a mask (not shown), an impurity of the other of the first conductivity type and the second conductivity type is introduced to the portion of the semiconductor layer 2 exposed from the mask. This way, the first contact region 13 of the first conductivity type that is in contact with the side surface 21b of the trench 21, and the second contact region 14 of the second conductivity type that is separated from the first contact region 13 are formed.

In this embodiment, an impurity of the second conductivity type is introduced into the main surface 2a of the semiconductor layer 2 and the surrounding area in the impurity region 115. This way, the second impurity region 15 and the second contact region 14 located on the second impurity region 15 and in contact with the second impurity region 15 are formed.

By performing Steps 1 to 5 described above, the Zener diode 6 (see FIG. 2) having the first impurity region 11 and the trench structure 12, as well as the first contact region 13, the second contact region 14, and the second impurity region 15 that function as a current path for the Zener diode 6 are formed.

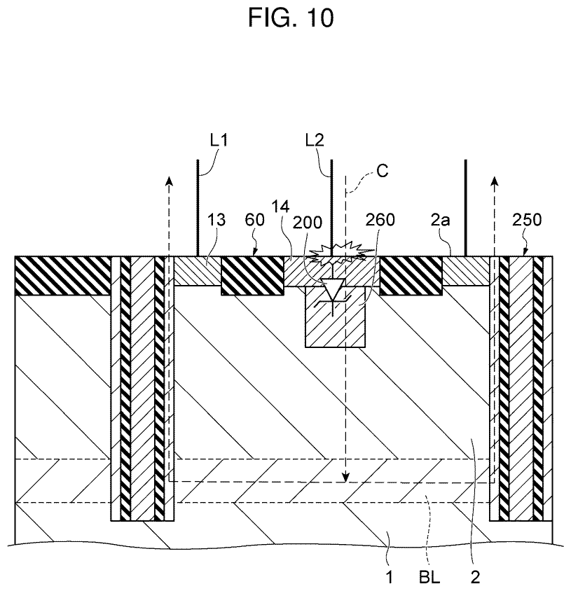

Next, with reference to FIG. 10 described below, the actions and effects of the semiconductor device 100 manufactured by the manufacturing method of this embodiment described above will be explained. FIG. 10 is a schematic cross-sectional view showing a semiconductor device according to a reference example. FIG. 10 illustrates a Zener diode 200. Unlike the Zener diode 6, the Zener diode 200 does not have the first impurity region 11, the trench structure 12, or the second impurity region 15. Instead, the Zener diode 200 has a trench structure 250 that is DTI in contact with the first contact region 13, and an impurity region 260 of the first conductivity type that is in contact with the second contact region 14. The trench structure 250 has a structure similar to the trench structure 50 of the Zener diode 6, and is adjacent to the second contact region 14. The impurity region 260 is located directly below the second contact region 14 and is separated from the buried region BL.

In the Zener diode 200, a PN junction is formed by the second contact region 14 and the impurity region 260. The second contact region 14 is formed on the main surface 2a of the semiconductor layer 2. This means that the performance of the Zener diode 200 is likely to be affected by the quality of the surface of the second contact region 14. Also, in the Zener diode 200, a current C flowing from the second contact region 14 to the first contact region 13 mainly passes through the impurity region 260, the semiconductor layer 2, the buried region BL, and the surface of the trench structure 250. Therefore, the thicker the semiconductor layer 2, the greater the parasitic resistance of the current path that runs through the Zener diode 200.

On the other hand, the Zener diode 6 included in the semiconductor device 100 of the embodiment above has the first impurity region 11, the trench structure 12, and the second impurity region 15. In the Zener diode 6, the third impurity region 16 that constitutes the side surface 21b of the trench 21 of the trench structure 12 forms a PN junction with the second impurity region 15. In this case, a part of the Zener diode 6 where the PN junction is formed is separated from the main surface 2a of the semiconductor layer 2. This makes the performance of the Zener diode 6 less susceptible to the effect of the quality of the main surface 2a of the semiconductor layer 2. Therefore, according to the embodiment above, it is possible to provide the semiconductor device 100 capable of reducing surface noise, and as a result, the Zener diode 6 is less likely to have a drift than the Zener diode 200.

In the embodiment above, because the first impurity region 11, the trench structure 12, and the second impurity region 15 are located above the buried region BL, the parasitic resistance R of the current path passing through the Zener diode 6 is less likely to change even if the thickness of the semiconductor layer 2 increases. In addition, the current path in the Zener diode 6 is significantly shorter than that of the Zener diode 200. Thus, the internal resistance of the Zener diode 6 can be significantly smaller than the internal resistance of the Zener diode 200.

Furthermore, in the embodiment above, the trench structures 12 and 50 having differing depths are formed at the same time. Specifically, by making the width W1 of the trench 21 of the trench structure 12 differ from the width W2 of the trench 51 of the trench structure 50, the trench 21 having the semiconductor layer 2 as the bottom surface thereof and the trench 51 that runs through the semiconductor layer 2 can be formed simultaneously in Step 2A described above. Also, the insulator 22 of the trench structure 12 and the insulating layer 52 of the trench structure 50 can be formed simultaneously in Steps 2C and 2D described above, and the conductor 23 of the trench structure 12 and the conductor 53 of the trench structure 50 can be formed simultaneously in Step 2E described above. This makes it possible to form a plurality of types of trench structures 12 and 50 simultaneously without increasing the number of manufacturing steps for the semiconductor device 100. Therefore, by applying the manufacturing method of the semiconductor device 100 according to the embodiment above, it is possible to efficiently manufacture a plurality of types of trench structures.

In the embodiment above, by simultaneously forming a plurality of types of trench structures (i.e., trench structures 12, 50), it is possible to simultaneously form the trench structure 50, which is a DTI, and the Zener diode 6 using the trench structure 12. Therefore, in the embodiment above, a process of forming a trench structure just for the Zener diode 6 can be omitted. That is, a mask for forming a trench structure just for the Zener diode 6 can be omitted. This makes it possible to effectively reduce the manufacturing cost of the semiconductor device 100 including the Zener diode 6 and the trench structure 50 (DTI).

In one example, the ratio of the width W1 of the trench 21 to the depth D1 of the trench 21 is 27% or greater and less than or equal to 960% of the ratio of the width W2 of the trench 51 to the depth D2 of the trench 51, for example. In this case, when the trench 51 that runs through the semiconductor layer 2 is formed, the bottom surface 21a of the trench 21 can be easily defined by the semiconductor layer 2.

In one example, the impurity concentration of the second contact region 14 is greater than the impurity concentration of the first impurity region 11 and the impurity concentration of the second impurity region 15. In this case, it is possible to effectively reduce the contact resistance of the Zener diode 6 and the wiring L2.

In one example, the semiconductor layer 2 has the third impurity region 16 of the first conductivity type that constitutes the side surface 21b of the trench 21, and the first impurity region 11 and the first contact region 13 are each in contact with the third impurity region 16. In this case, it is possible to effectively reduce the internal resistance of the Zener diode 6.

In one example, the semiconductor device 100 includes the insulator 62 that fills up the recess 61 provided on the main surface 2a of the semiconductor layer 2, and the insulator 62 is located between the first contact region 13 and the second contact region 14. In this case, it is possible to effectively reduce a leak current between the first contact region 13 and the second contact region 14.

In one example, the semiconductor device 100 has the conductor 23 embedded in the trench 21, and the conductor 23 is in a floating state. In this case, it is possible to reduce the parasitic resistance R in the electric current path that goes through the Zener diode 6 in a portion near the conductor 23.

In one example, the manufacturing method includes Step 2B of introducing an impurity of the first conductivity type into the side surface 21b of the trench 21 and the side surface 51b of the trench 51 before the insulator 22 and the insulating layer 52 are formed. In this case, the third impurity region 16 that becomes a part of the current path of the Zener diode 6 can be formed simultaneously with the fourth impurity region 17 included in the trench structure 50, and therefore, the manufacturing process can be simplified effectively.

In one example, each of the conductors 23 and 53 is polysilicon. In this case, it is possible to embed the conductors 23 and 53 respectively in the trenches 21 and 51 easily.

An embodiment of one aspect of the present disclosure has been described, but the present disclosure may be embodied in other forms.

In the embodiment above, the Zener diode is located on the semiconductor substrate, but the present disclosure is not limited thereto. In one example, the Zener diode may be located on a substrate of other types than a semiconductor substrate. In this case, the semiconductor layer is formed on that substrate. That is, the semiconductor layer does not necessarily have to be formed on the semiconductor substrate. If the semiconductor substrate is not used, the conductor of the trench structure, which is DTI, does not have to be in contact with the substrate.

In the embodiment above, the semiconductor device can be applied to a power module used for an inverter circuit that drives electric motors used as power sources for automobiles (including electric vehicles), trains, industrial robots, air conditioners, air compressors, electric fans, vacuum cleaners, dryers, refrigerators and the like, for example. The semiconductor device can be applied to a power module used for an inverter circuit of a power generator such as a solar panel and wind power generator. Alternatively, the semiconductor device can be applied to a circuit module that constitutes an analog control power supply, a digital control power supply, or the like.

Although an embodiment of one aspect of the present disclosure has been described in detail above, these are merely specific examples used to clarify the technical content of the present disclosure, and the present disclosure should not be interpreted as being limited to these specific examples, and the scope of the present disclosure is limited only by the appended claims As described above, various embodiments in this disclosure may be specified as follows.

Below, representative examples extracted from the present specification and descriptions of the drawings will be explained.

### A1

A semiconductor device, including:
a semiconductor layer of a first conductivity type located on a substrate;
a trench that has the semiconductor layer as a bottom surface thereof; and
an insulating layer that covers a surface of the trench,
wherein the semiconductor layer includes:
a first impurity region of a second conductivity type that differs from the first conductivity type, the first impurity region being separated from the substrate and in contact with a side surface of the trench;
a first contact region of the first conductivity type located on the first impurity region in a surface portion of the semiconductor layer and in contact with the side surface of the trench;
a second contact region of the second conductivity type located on the first impurity region in the surface portion of the semiconductor layer and separated from the first contact region; and
a second impurity region of the second conductivity type located on the first impurity region below the second contact region and in contact with both the first impurity region and the second contact region, and
wherein the first impurity region and the first contact region are separated from each other.

### A2

The semiconductor device according to [A1], wherein an impurity concentration of the second contact region is greater than an impurity concentration of the first impurity region and an impurity concentration of the second impurity region.

### A3

The semiconductor device according to [A1] or [A2], wherein the semiconductor layer further includes a third impurity region of the first conductivity type constituting the side surface of the trench, and
wherein each of the first impurity region and the first contact region is in contact with the third impurity region.

### A4

The semiconductor device according to any one of [A1] to [A3], further including an insulator that fills up a recess formed in the surface portion of the semiconductor layer,
wherein the insulator is located between the first contact region and the second contact region.

### A5

The semiconductor device according to any one of [A1] to [A4], further including a conductor embedded in the trench,
wherein the conductor is in a floating state.

### A6

The semiconductor device according to [A5], wherein the conductor is polysilicon.

### A7

The semiconductor device according to any one of [A1] to [A6], further including a second trench that runs through the semiconductor layer and surrounds the trench,
wherein a width of the second trench is larger than a width of the trench.

### A8

The semiconductor device according to [A7], wherein a ratio of the width of the trench to a depth of the trench is 27% or more and 960% or less of a ratio of the width of the second trench to a depth of the second trench.

### A9

A manufacturing method of a semiconductor device, including:
forming a semiconductor layer of a first conductivity type located on a substrate;
forming a trench having the semiconductor layer as a bottom surface thereof, the trench being located in the semiconductor layer and adjacent to a first impurity region of a second conductivity type that differs from the first conductivity type;
forming a second impurity region of the second conductivity type in the semiconductor layer, the second impurity region being on the first impurity region and in contact with the first impurity region; and
forming a first contact region of the first conductivity type located on the first impurity region in a surface portion of the semiconductor layer and in contact with a side surface of the trench, and a second contact region of the second conductivity type located on the first impurity region in the surface portion of the semiconductor layer and separated from the first contact region.

### A10

The manufacturing method of a semiconductor device according to [A9], further including, prior to the formation of the second impurity region:
forming an insulator that fills up the trench;
removing a part of the insulator such that the bottom surface of the trench is not exposed; and
embedding in the trench a conductor separated from the semiconductor layer,
wherein the conductor is in a floating state.

### A11

The manufacturing method of a semiconductor device according to [A10], wherein, in the step of forming the trench, a second trench that runs through the semiconductor layer is formed simultaneously with the trench,
wherein, in the step of forming the insulator, an insulating layer that covers the second trench is simultaneously formed,
wherein, in the step of removing a part of the insulator, a part of the insulating layer is removed such that the substrate is exposed from the second trench,
wherein, in the step of embedding the conductor in the trench, a second conductor that is in contact with the substrate is embedded in the second trench, and
wherein a width of the second trench is greater than a width of the trench.

### A12

The manufacturing method of a semiconductor device according to [A11], wherein the substrate is a semiconductor substrate.

### A13

The semiconductor device according to [A11] or [A12], wherein a ratio of the width of the trench to a depth of the trench is 27% or more and 960% or less of a ratio of the width of the second trench to a depth of the second trench.

What is claimed is:

1. A semiconductor device, comprising:
a semiconductor layer of a first conductivity type that is located on a substrate;
a trench that has the semiconductor layer as a bottom surface thereof; and
an insulating layer that covers a surface of the trench,
wherein the semiconductor layer includes:
a first impurity region of a second conductivity type that differs from the first conductivity type, the first impurity region being separated from the substrate and in contact with a side surface of the trench;
a first contact region of the first conductivity type that is located on the first impurity region in a surface portion of the semiconductor layer and that is in contact with the side surface of the trench;
a second contact region of the second conductivity type that is located on the first impurity region in the surface portion of the semiconductor layer and that is separated from the first contact region; and
a second impurity region of the second conductivity type that is located on the first impurity region below the second contact region and that is in contact with both the first impurity region and the second contact region, and
wherein the first impurity region and the first contact region are separated from each other.

2. The semiconductor device according to claim 1, wherein an impurity concentration of the second contact region is greater than an impurity concentration of the first impurity region and an impurity concentration of the second impurity region.

3. The semiconductor device according to claim 1, wherein the semiconductor layer further includes a third impurity region of the first conductivity type that constitutes the side surface of the trench, and
wherein each of the first impurity region and the first contact region is in contact with the third impurity region.

4. The semiconductor device according to claim 1, further comprising an insulator that fills up a recess formed in the surface portion of the semiconductor layer,
wherein the insulator is located between the first contact region and the second contact region.

5. The semiconductor device according to claim 1, further comprising a conductor embedded in the trench,
wherein the conductor is in a floating state.

6. The semiconductor device according to claim 5, wherein the conductor is polysilicon.

7. The semiconductor device according to claim 1, further comprising a second trench that runs through the semiconductor layer and surrounds the trench,
wherein a width of the second trench is larger than a width of the trench.

8. The semiconductor device according to claim 7, wherein a ratio of the width of the trench to a depth of the trench is 27% or more and 960% or less of a ratio of the width of the second trench to a depth of the second trench.

9. A manufacturing method of a semiconductor device, comprising:
forming a semiconductor layer of a first conductivity type that is located on a substrate;
forming a trench having the semiconductor layer as a bottom surface thereof, the trench being located in the semiconductor layer and adjacent to a first impurity region of a second conductivity type that differs from the first conductivity type;
forming a second impurity region of the second conductivity type in the semiconductor layer, the second impurity region being on the first impurity region and in contact with the first impurity region; and
forming a first contact region of the first conductivity type located on the first impurity region in a surface portion of the semiconductor layer and in contact with a side surface of the trench, and a second contact region of the second conductivity type located on the first impurity region in the surface portion of the semiconductor layer and separated from the first contact region.

10. The manufacturing method of a semiconductor device according to claim 9, further comprising, prior to the formation of the second impurity region:
forming an insulator that fills up the trench;
removing a part of the insulator such that the bottom surface of the trench is not exposed; and
embedding in the trench a conductor separated from the semiconductor layer,
wherein the conductor is in a floating state.

11. The manufacturing method of a semiconductor device according to claim 10, wherein, in the step of forming the trench, a second trench that runs through the semiconductor layer is formed simultaneously with the trench,
wherein, in the step of forming the insulator, an insulating layer that covers the second trench is simultaneously formed,
wherein, in the step of removing a part of the insulator, a part of the insulating layer is removed such that the substrate is exposed from the second trench,
wherein, in the step of embedding the conductor in the trench, a second conductor that is in contact with the substrate is embedded in the second trench, and
wherein a width of the second trench is greater than a width of the trench.

12. The manufacturing method of a semiconductor device according to claim 11, wherein the substrate is a semiconductor substrate.

13. The manufacturing method of a semiconductor device according to claim 11, wherein a ratio of the width of the trench to a depth of the trench is 27% or more and 960% or less of a ratio of the width of the second trench to a depth of the second trench.
